(19) United States
(12) Patent Application Publication
(10) Pub. No.: US 2019/0327355 A1
(43) Pub. Date: Oct. 24, 2019

(54) HANDS FREE ON CALL PHONE (FONCPH)

(71) Applicant: Katrina Goff CANDY, Moama (AU)

(72) Inventor: Katrina Goff CANDY, Moama (AU)

(21) Appl. No.: 16/182,576

(22) Filed: Nov. 6, 2018

(30) Foreign Application Priority Data
Nov. 7, 2017 (AU) 2017904507

(51) Int. Cl. H04M 1/60; H04R 5/033; G10L 15/30; G06F 1/16; H01L 31/05

(52) U.S. Cl. CPC H04M 1/6041; H04R 5/033; H01L 31/0508; G06F 1/163; G10L 15/30

(57) ABSTRACT

The Free On Call Phone (FONCHP) devices are mobile style telecommunications mechanisms which allows a user to make and receive telephone calls in a hands-free manner. The FONCHP devices comprise an earpiece and incorporates all the features of a smartphone and/or mobile electronic tablet but without the need for using one's hands. The FONCHP devices are voice sound activated and controlled by voice prompts, commands given by the user to which the FONCHP devices are programmed to respond.

### CROSS-REFERENCE TO RELATED APPLICATIONS

This application is a continuation Australian provisional utility patent application no. 2017904507 filed Nov. 7, 2017.

### FEDERALLY SPONSORED RESEARCH AND DEVELOPMENT

None.

### APPENDICES

None.

### BACKGROUND OF THE INVENTION

In recent years, the field of telecommunications has been revolutionized by the development of mobile telephony technology. Early on, mobile telecommunication devices comprised two-way pagers which allow users to communicate wirelessly through radio signal networks by brief text messages on small hand-held electronic appliances known as pagers; subsequently pagers developed into mobile telephones capable of free movement albeit within a terrestrial cellular area, otherwise known as a cell. Mobile telephones, as known as mobile phones, are often called cell phones if restricted to a cellular area and some mobile phones connect to satellites and therefore are called satellite phones. Mobile cell phones connect by a radio frequency within their cell, such is the technology of the current smartphone. With the development of increased computer power and capability the mobile phone has morphed into the smartphone they have become a hand-held portable computer telecommunication system capable of performing a multitude of highly sophisticated tasks. Along with smartphones, mobile portable electronic tablets have become very powerful and popular and as long as a user, whether of a smartphone or electronic tablet, is within range of a telecommunication radio signal, he/she can communicate and perform a variety of computer tasks with anyone virtually anywhere in the world.

The typical smartphone and/or electronic tablet is in effect a handheld personal computer possessing, enormous computer power along with extremely fast access to the world wide web. Smartphones usually are provided with a computer operating system, for example, iOS™, for Apple™ products or for Android™ for Google products, capable of processing numerous computer software applications, otherwise known as “apps”. These apps usually include a web browser, camera software, calendar software, etc. and are limited only by a user's desires. Additionally, a smartphone and/or electronic tablet device are usually provided with various sensors, such as accelerometers, magnetometers, proximity sensors, barometers, etc., giving them a wide range of sensing capabilities. The typical smartphone and/or electronic tablet usually contains similar components, a battery as a power source, some kind of input mechanism, usually a key pad or touch screen, a display mechanism to show input or received messages or texts, etc, mobile phone telephonic services allowing for users to call and/or text other users, and other apps, for performing various computing functions. The input mechanism many times will have sound input and output features. Many mobile electronic devices also are provided with short-range wireless communications features such a Bluetooth™ and/or other infrared connecting systems.

And yet as amazing as these developments have been, these mobile devices still require a user to operate the smartphone or electronic tablet by using one or both of their hands limiting their use. Consequently, there is a need for a hands-free electronic telecommunication device capable of performing all the functions of state-of-the-art smartphones and/or electronic tablets.

### SUMMARY OF THE INVENTION

The devices of the instant invention, known as the hands free on call phone, also known as FONCPH, fundamentally use an earpiece style mechanism to provide an electronic telecommunication apparatus having all the features and functionality of smartphones and/or mobile electronic tablets but with hands-free capability.

The FONCHP devices are mobile style telecommunications mechanisms which allows a user to make and receive telephone calls in a hands-free manner. The FONCHP devices comprises either an earpiece or headband and incorporates all the features of a smartphone and/or mobile electronic tablet but without the need for using one's hands. The FONCHP devices are voice sound activated and controlled by voice prompts, commands given by the user to which the FONCHP devices are programmed to respond.

Additionally, the FONCPH devices incorporate the various features of smartphones and mobile electronic tablets allowing the FONCPH devices to perform many of the same functions as a smartphone and/or electronic tablet but lacking a screen display. However, the FONCPH devices can synchronize and control alternate devices, such as a smartphone, mobile electronic tablet or pad, television, desktop or laptop computer, or interactive visual projector.

The FONCPH devices also include various apps including contacts, address book, calendar, phone, email, and Facebook™, and VoIP, a type of voice communications service delivering voice communications over the internet, and apps such as Skype, Viber, Facebook™ Messenger, YAHOO!™ Messenger, etc.

Additionally, the FONCPH devices are provided with the capability of providing notification of new messages which can be a new email, text or alternate app along with an option for very important persons, (VIP) notifications on priority messages. VIP notifications will be via voice prompts and visually on the FONCPH device.

The FONCPH device is further provided with an interactive voice menu feature for controlling FONCPH devices via user voice prompting and is constructed be configured for the personal preferences of a user. And if an error occurs during use, the FONCPH devices can voice prompt the User to rectify the error. Time can be determined by a voice prompt or by signal from the devices as well notification of the battery level and usage.

Similarly, the FONCPH devices are provided with a global positioning satellite (GPS) feature allowing for directions from a current location to a destination which is communicated by voice prompts to the User; concurrently, the FONCPH devices are provided with meteorological features to inform and make the User aware of surrounding environment weather conditions. As the FONCPH devices are primarily a voice prompting mechanism, it is much safer to use than current smartphone and/or mobile electronic device when driving on the road. as voice prompting is the primary function. Additionally, the FONCPH devices are particularly suitable for assisting disabled and visually impaired users by giving them interactive voice prompts for their operation.

The FONCPH devices are further provided with a number of accessories and attachments which can connect via wireless technology such as Bluetooth™, or similar technology, to small portable interactive projectors, portable screens or synchronize to smartphones and/or other mobile electronic devices. There are also accessories which can be plugged in though direct ports provided on the FONCPH devices and they have the capability of being charged either by solar cell, remote inductive, wireless, cordless and/or through direct port electrical connection charging.

The FONCPH devices are also provided with mobile phone and WI/FI™ radiation harmonizers constructed to neutralize electromagnetic radiation (EMR) which are considered hazardous to human organs and/or meridian Chinese medicine pathways.

### BRIEF DESCRIPTION OF THE DRAWINGS

FIG. 1A discloses a left-side view of the FONCPH device 1.

FIG. 1B discloses a right-side view of the FONCPH device 1.

FIG. 1C discloses the front view of the FONCPH device 1.

FIG. 1D discloses the rear view of the FONCPH device 1.

FIG. 2A discloses a left-side view of the FONCPH device 11.

FIG. 2B discloses a right-side view of the FONCPH device 11.

FIG. 2C discloses the front view of the FONCPH device 11.

FIG. 2D discloses the rear view of the FONCPH device 11.

FIG. 3A discloses a left-side view of the FONCPH device 21.

FIG. 3B discloses a right-side view of the FONCPH device 21.

FIG. 3C discloses the front view of the FONCPH device 21.

FIG. 3D discloses the rear view of the FONCPH device 21.

FIG. 3E discloses components of the FONCPH device 21.

FIG. 4A discloses a side view of FONCPH accessory 31.

FIG. 4B discloses a rear view of FONCPH accessory 31.

FIG. 4C discloses a top view of FONCPH accessory 31.

FIG. 5A is a three quarters perspective right hand view of the accessory 40.

FIG. 5B discloses a rear view of the accessory 40.

FIG. 5C discloses a side view of accessory 40.

FIG. 5D discloses a top view of the accessory 40.

FIG. 6A discloses a is a three quarters perspective right hand view of the accessory 60.

FIG. 6B discloses a rear view of the accessory 60.

FIG. 6C discloses a side view of the accessory 60.

FIG. 6D discloses a top view of the accessory 60.

### DETAILED DESCRIPTION OF THE INVENTION

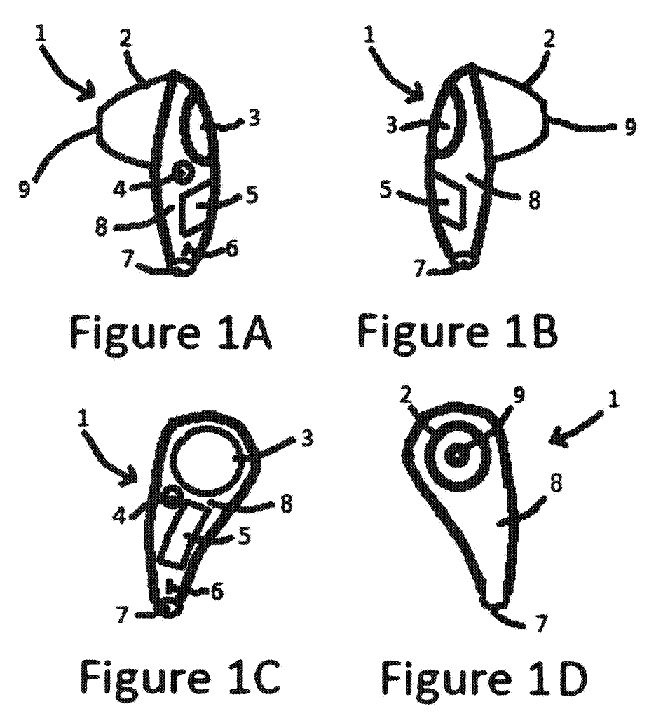

FIG. 1A to 1D show a first embodiment of the FONCPH device 1 in the form of an earpiece mechanism.

Particularly, FIG. 1A shows a left-side view of the FONCPH device 1 having a protruding tip 2, capable of being inserted into a human ear, and an integral oval shaped body 8. Protruding tip 2 is provided with aperture 9 allowing for sound to be transmittable to an earphone (not shown) located inside body 8. On the opposite side of body 8 from the tip 2 is a solar panel 3 capable of powering the FONCPH device 1. Below the solar panel 3, on body 8, is a camera 4 and a power button 5 used to activate and deactivate the FONCPH device 1. Additionally, below power button 5, is a microphone 6 and at the bottom portion of body 8 is port 7 allowing for the connection of an electrical charging appliance (not shown) or other accessories to be connected to the FONCPH device 1.

FIG. 1B shows a right-side view of the FONCPH device 1 with the protruding tip 2, aperture 9, integral oval shaped body 8 and solar panel 3. Below the solar panel 3 is located the power button 5 and port 7.

FIG. 1C shows the front view of the FONCPH device 1 revealing the circular shaped solar panel 3, camera 4, power button 5, microphone 6, and port 7.

FIG. 1D shows the rear view of the FONCPH device 1 revealing the integral oval shaped body 8, protruding tip 2 with aperture 9.

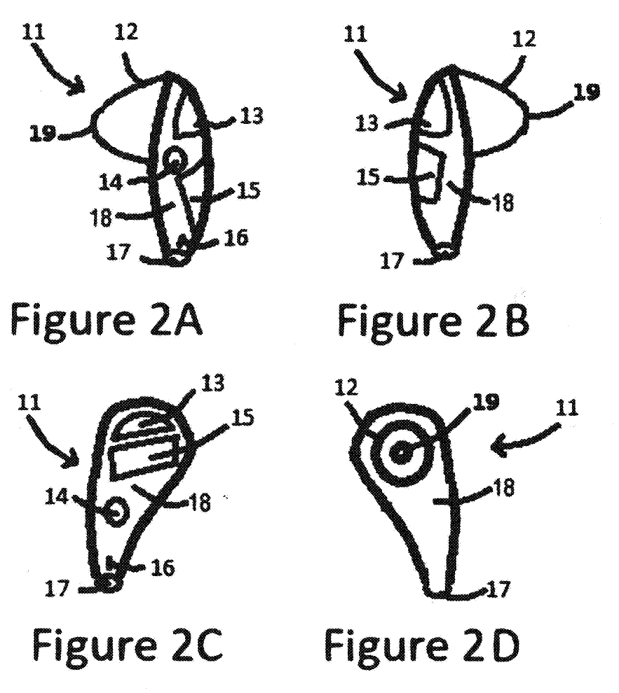

FIGS. 2A to 2D show a second embodiment of the FONCPH device 11 in the form of an earpiece mechanism.

Particularly, FIG. 2A shows a left-side view of the FONCPH device 11 having a protruding tip 12, capable of being, inserted into a human ear, and an integral oval shaped body 18. Protruding tip 12 is provided with aperture 19 allowing for sound to be transmittable to an earphone (not shown) located inside body 18. On the opposite side of body 18 from the tip 12 is a solar panel 13 capable of powering the FONCPH device. Below the solar panel 13, on body 18, is a camera 14 and a power button 15 used to activate and deactivate the FONCPH device 11. Additionally, below the power button 15 is a microphone 16 and at the bottom portion of body 18 is port 17 allowing for connection of electrical charging appliance and other accessories to FONCPH device 11.

FIG. 2B shows a right-side view of the FONCPH device 11 with the protruding tip 12 and integral oval shaped body 18 and solar panel 13. Below the solar panel 13 is located the power button 15 and port 17.

FIG. 2C shows the front view of the FONCPH device 11 revealing the semi-circular shaped solar panel 13, power button 15, camera 14, microphone 16, and port 17.

FIG. 2D shows the rear view of the FONCPH device 11 revealing the integral oval shaped body 18, protruding tip 12 with aperture 19.

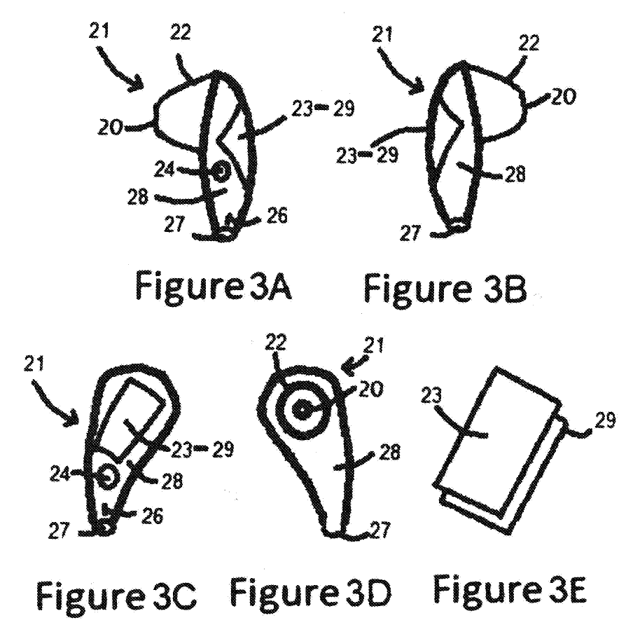

FIGS. 3A to 3E show a third embodiment of the FONCPH device 21 in the form of an earpiece mechanism.

Particularly, FIG. 3A shows a left-side view of the FONCPH device 21 having a protruding tip 22, capable of being inserted into a human ear, and an integral oval shaped body 28. Protruding tip 22 is provided with aperture 20 allowing for sound to be transmittable to an earphone (not shown) located inside body 28. On the opposite side of body 28 from the tip 22 is a bi-layer panel component 23-29, the power button comprising two layers as shown in and discussed in reference to FIG. 3E. Below component 23-29, on body 28, is a camera 24. Additionally, below component 23-29, is microphone 26 and at the bottom portion of body 28 is port 27 allowing for the connection of an electrical charging appliance and other accessories to FONCPH device 21.

FIG. 3B shows a right-side view of the FONCPH device 21 with the protruding tip 22 with aperture 20, integral oval shaped body 28 and bi-layer component 23-29. Below the bi-layer component 23-29 is port 27.

FIG. 3C shows the front view of the FONCPH device 21 revealing bi-layer component 23-29, camera 24, integral oval shaped body 28, microphone 26, and port 27.

FIG. 3D shows the rear view of the FONCPH device 21 revealing the integral oval shaped body 28, protruding tip 22 with aperture 20 and port 27.

FIG. 3E shows the details of component 23-29 of FIGS. 3A to 3D, particularly component top transparent layer 23, the power button, and layer component 29 comprising a solar panel used to power FONCPH device 21.

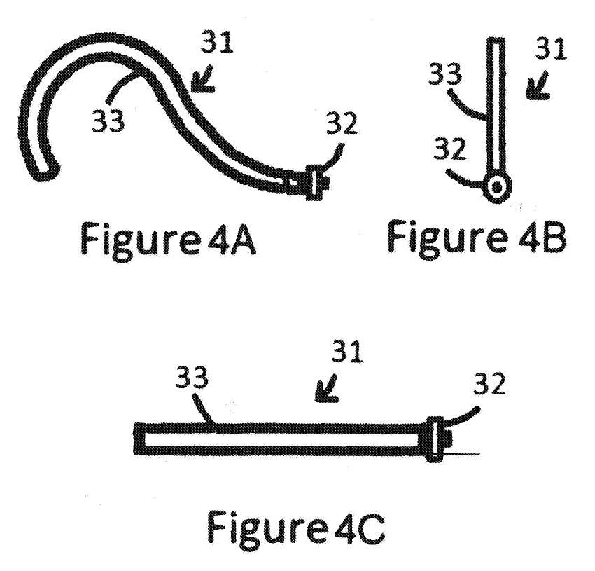

FIGS. 4A to 4C disclose a first accessory useable with ail the FONCPH devices 1, 11, or 21.

Particularly, FIG. 4A reveals a side view of FONCPH accessory 31 showing an elliptical shaped ear piece support 31 capable of being attached, by end piece 32, to the charge or accessory port 7, 17 or 27 of FONCPH devices 1, 11, or 21 respectively. When attached to any of the FONCPH devices and placed over a user ear, support 31 provides added reinforcement for the FONCPH devices.

FIG. 4B shows a rear view of FONCPH accessory 31 showing an elliptical shaped ear piece support 33 capable of being attached, by end piece 32, to the charge or accessory port 7, 17 or 27 of FONCPH devices 1, 11, or 21, respectively.

FIG. 4C shows a top view of FONCPH accessory 31 showing an elliptical shaped ear piece support 33 capable of being attached, by end piece 32, to the charge or accessory port 7, 17 or 27 of FONCPH devices 1, 11, or 21 respectively.

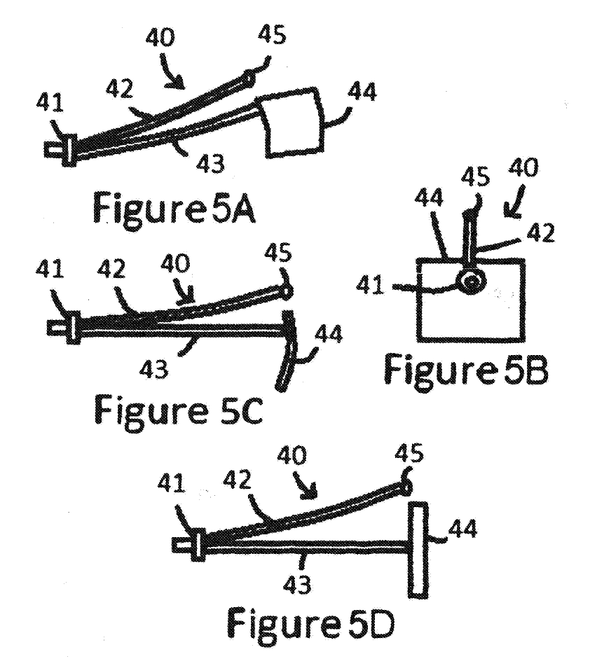

FIGS. 5A to 5D disclose a second accessory useable with all of the FONCPH devices 1, 11, and 21.

Particularly, FIG. 5A is a three-quarters perspective right hand view of camera display accessory 40 which assists and facilitates the taking of a user self-picture, also known as “selfies”. Accessory 40 consists of an elongated flexible electrical cable 42 provided at one end to a portal connector 41 and at the opposite end with a camera 45. Accessory 40 is further provided with a second elongated flexible electrical cable 43 affixed on one end to portal connector 41 and its opposite end with a visual display screen 44. Visual display screen 44 incorporates touch-screen digitizer technology involving a multilayered “sandwich” construction in which images are produced on a bottom layer while the middle layer comprises a transparent sheet and a protective hard layer forms a top layer; the middle layer, called the digitizer, consists of microscopic sensors which when connected to an electronic circuit and appropriate software can be triggered by finger touch to activate the software and produce a desired result and/or feature. Visual display screen is connected through elongated electronic cable 43 and through portal connector 41 to either portal 7, 17, or 27 of the respective FONCPH device for activation and operation. In use, portal connector 41 is inserted into the charge or accessory port 7, 17 or 27 of FONCPH devices 1,11, or 21 respectively, and the User may then aim the camera 45 to take a selfie and then be able to view the selfie on the display screen 44.

FIG. 5B reveals a rear view of camera display accessory 40 of FIG. 5A with portal connector 41, elongated flexible electrical cable 42 and camera 45. Also shown in FIG. 5B is visual display screen 44.

FIG. 5C reveals a side view of camera display accessory 40 of FIG. 5A with portal connector 41, elongated flexible electrical cable 42 and camera 45. Also shown in FIG. 5C is second elongated flexible electrical cable 43 affixed on one end to portal connector 41 and its opposite end with a visual display screen 44.

FIG. 5D reveals a top view of camera display accessory 40 of FIG. 5A with portal connector 41, elongated flexible electrical cable 42 and camera 45. Also shown in FIG. 5D is second elongated flexible electrical cable 43 affixed on one end to portal connector 41 and its opposite end with a visual display screen 44.

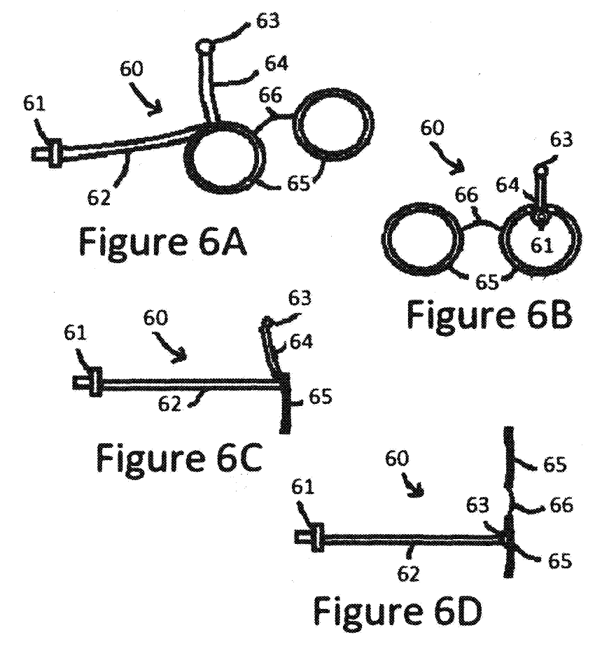

FIG. 6A to 6D show a third accessory useable with all of the FONCPH devices 1, 11, and 21.

Particularly, FIG. 6A reveals a three-quarters perspective right hand view of transparent digitizer screen accessory device 60 consisting of an elongated flexible electrical cable 62 affixed on one end to portal connector 61 and on its opposite end with a pair of visual display screens 65 in the form of a pair of optical glasses with a nose bridge 66. Visual display screens 65, similar to visual screen 44 of accessory 40, incorporates touch-screen digitizer technology involving multilayered “sandwich” construction in which images are produced on a bottom layer while the middle layer comprises a transparent sheet and a protective hard layer forms a top layer; the middle layer, called the digitizer, consists of microscopic sensors which when connected to an electronic circuit and appropriate software can be triggered by finger touch to activate the software and produce a desired result and/or feature. In use, visual display screens 65 are connected through elongated electronic cable 62 and through portal connector 61 to either portal 7, 17, or 27 of the respective FONCPH device for activation and operation. Also attached to cable 62 and screen 65 is elongated electrical cable 64 provided an end with camera 63. In use, portal connector 61 is inserted into the charge or accessory port 7, 17 or 27 of FONCPH devices 1, 11, or 21 respectively, and a user then places the accessory device 60 on the nose bridge of the User and the User may then aim the camera 63 to take a selfie and then be able to view the selfie on display screens 65.

FIG. 6B reveals a rear view of the transparent digitizer screen accessory 60 of FIG. 6A with portal connector 61, elongated flexible electrical cable 64 and camera 63. Also shown in FIG. 6B are the pair of visual displays screens 65 and nose bridge 66.

FIG. 6C reveals a side view of transparent digitizer screen accessory 60 of FIG. 6A with portal connector 61, elongated flexible electrical cable 64 and camera 63. Also shown in FIG. 6C is second elongated flexible electrical cable 62 affixed on one end to portal connector 61 and its opposite end with a visual display screen 65.

FIG. 6D reveals a top view of transparent digitizer screen accessory 60 of FIG. 6A with portal connector 61, elongated flexible electrical cable 62 and camera 63. Also shown in FIG. 6D is elongated flexible electrical cable 62 affixed on one end to portal connector 61 and its opposite end with a visual display screen 65 and nose bridge 66.

Having described in detail the various components of the FONCPH devices and accessories herein, their operation and use will now be described.

Now referring to FIGS. 1A to 1D, 2A to 2D, and 3A to 3E, FONCPH devices 1, 11, 21, respectively comprise an earpiece style earphone with the same functionality as a smartphone or other mobile electronic tablets but with hands-free capability. The FONCHP device 1 is provided with an earphone hearing mechanism located within protruding tip 2; for FONCPH device 11, the earphone hearing mechanism is located in protruding tip 12 and for FONCPH device 21, the earphone hearing mechanism is located in protruding tip 22. Aperture 9 of protruding tip 2, for FONCPH device 1 allows for sound be transmitted to FONCPH device 1 earphone; similarly, apertures 19 and 20 perform the same function for FONCPH devices 11, and 21 respectively. Also located with bodies 8, 18 and 28 is electronic microchip hardware and software capable electronically operating the FONCPH devices 1, 11, and 21.

Additionally, FONCPH device 1 is provided with an electronic transmitter and transceiver and computer software, located with electronical components of FONCPH body 8 capable of connecting FONCPH device 1 with a terrestrial telecommunication cellular area, and/or radio towers and subsequently with a telecommunication satellite and system allowing FONCPH device 1 to communicate with any electronic device, world-wide, connectable to the telecommunication satellite and system. For FONCPH devices 12 and 21, a similar electronic transmitter and transceiver and computer software are located with the electronic components of bodies 18 and 28, respectively. FONCPH device 1 further is provided with computer software applications, within FONCPH device 1 body 8, capable of receiving and transmitting signals to and from telecommunication cellular and navigational positioning systems, such as Global Positioning System, i.e., GPS, or Global Navigational Satellite System, i.e., GLONASS which allows for FONCPH device 1 to be located anywhere in the World; FONCPH devices 11 and 21 are similarly provided computer software applications within bodies 18 and 28 capable of sending and receiving signals to and from GPS and/or GLONASS systems.

Additionally, FONCPH device 1 is provided with a computer application software, i.e., otherwise known as the FONCPH app, which app is capable of processing any signals sent or received by FONCPH device 1 and additionally producing and receiving user audio command prompts for operating FONCPH device 1; similarly, FONCPH devices 11 and 21 has the FONCPH app capable of processing any signals sent or received by FONCPH devices 11 and 21, respectively, and producing and receiving user audio command prompts for operating FONCPH device 11 and 21. Additionally, FONCPH device 1 is provided with microphone 6, through which a user can speak and give voice commands which are produced and processed by the FONCPH app; for FONCPH devices 11 and 21, microphone 16 and 26 is provided. The FONCPH app further provides an interactive voice menu feature, for controlling the FONCPH devices 1, 11, or 21 via user voice prompting and the interactive voice menu feature is capable of being configured for the personal preferences of a user. The FONCPH interactive voice menu feature is constructed that in the event an error occurs during use, FONCPH device 1, 11 or 21 will voice prompt the User to rectify the error. In addition to these features, time can be determined by a voice prompt from a user or by signal from the device. Similarly, the FONCPH devices 1, 11, or 21 global positioning satellite (GPS) feature allows for directions from a current location to a destination to be communicated by voice commands and prompts to the user. Concurrently the FONCPH app is provided with meteorological feature to inform and make the user aware of surrounding environment weather conditions for each of FONCPH devices 1, 11, or 21. Each FONCPH device 1, 11, or 21 is provided, on their respective bodies, 8, 18 and 28, with cameras 4, 14, and 24 respective which can be operated by a user at will. Also, each FONCPH device 1, 11, or 21 is provided, on their respective bodies, 8, 18 and 28, with power button 5, 15, and 25, respectively for activating and deactivating the device.

Additionally, FONCPH devices 1, 11 or 21 are provided with an electrical battery source, not shown, located in body 8, 18, or 28, respectively, which can charge the devices via an electrical source through port 7, 17, or 27, respectively as well as by solar cells 3, 13, or 29 respectively. Alternatively, the electrical battery source of FONCPH devices 1, 11, or 21 can be charged by remote inductive charging, or wireless electrical charging. Similarly, FONCPH devices 1, 11, or 21 can advise or notify a user of the battery level and usage.

The FONCPH devices 1, 11, and 21, further incorporate the various features of smartphones and mobile electronic tablets allowing the FONCPH to perform many of the same functions as a smartphone and/or electronic tablet but lacking a screen display. Particularly, FONCPH devices 1, 11, or 21 can connect via wireless technology, such as Bluetooth™, or similar technology, and synchronize and/or control alternate devices, such as a smartphone, mobile electronic tablet or pad, television, desktop or laptop computer, or interactive visual projector. Further, the FONCPH device 1, 11, and 21 through the use of the FONCPH app, include various other computer software application software including such as Contacts, Address Book, Calendar, Facebook™, and VoIP, a type of voice communications service delivering voice communications over the internet. Additionally, the FONCPH app is compatible with various other computer software applications such as such as Skype, Viber, Facebook™ Messenger, YAHOO!™ Messenger, etc. Additionally, the FONCPH devices 1, 11 and 21, through the FONCPH app are provided with the capability of providing notification of new messages which can be a new email, text or alternate computer software applications along with an option for very important persons, (VIP), notifications on priority messages. VIP notifications, by the use of the FONCPH app can be accessed by a user via voice prompts and commands on the FONCPH devices 1, 11 and 21. As the FONCPH devices 1, 11, and 21, are primarily a voice prompting mechanism, they are much safer to use than current smartphone and/or mobile electronic device when driving on the road. as voice prompting is the primary function. Similarly, FONCPH devices 1, 11, and 21 are particularly suitable for assisting disabled and visually impaired users by giving them interactive voice prompts for its operation.

Finally, FONCPH device 1, 11 and 21 are further provided with a mobile phone and WI/FI™ radiation harmonizer, with the FONCPH app which harmonizer is constructed to neutralize electromagnetic radiation (EMR) which is considered hazardous to human organs and/or meridian Chinese medicine pathways.

In operation, be it FONCPH device 1, 11, or 21, a user will place the respective device in either of the User's ear, and activate the device by pushing power button 5, 15, or 25, respectively. The User will then give a voice command prompt to the device, for example, to ask for the current location and/or weather conditions. The User may then prompt the device to request a calendar for the day, particularly for tasks the User needs to perform. If the User wishes to make a telephone call, the User uses a command prompt to make a call. After the User has performed various tasks, he or she can prompt the device to power down the device or push the power button to deactivate it.

In the event, the User desires enhanced physical support for any of the devices, he or she can place accessory 31 over either ear and insert the respective FONCPH device 1, 11, or 21 into end piece 32.

Now referring to FIGS. 5A to 5D, the operation of accessory 40 is discussed. Camera display accessory 40 is an accessory useable with any of the FOHNCP devices 1, 21, or 31 and is composed of a camera 45 attached and extending by elongated electrical cable 42 to portal connector, connectable into port 7, 17, or 27 of FOHNCPH devices 1, 21, or 31 respectively. A user will assemble FOHNCPH device and accessory 40 together and then place the assembled FONCPH device and accessory 40 into a user's ear by use of earpiece 2, 12, or 22 of either FONCPH device 1, 21, or 31, respectively. Accessory 40 is further provided with a second elongated flexible electrical cable 43 affixed on one end to portal connector 41 and its opposite end with a visual display screen 44. In, use after being inserted into charge or accessory port 7, 17 or 27 of FONCPH devices 1, 11, or 21 respectively, the User may then aim the camera 45 to take a selfie, or a picture of him/herself, by use of voice command prompts to instruct the FONCPH device to activate the camera feature and then be able to view the selfie on the display screen 44, again, by voice commanding the FONCPH device to activate the display screen feature.

Now referring to FIGS. 6A to 6D, the operation of accessory 60 is discussed. Transparent digitizer screen accessory device 60 is useable with any of the FONCPH devices 1, 21, or 31 and consists of an elongated flexible electrical cable 62 affixed on one end to portal connector 61 and on its opposite end with a pair of visual display screens 65 in the form of the style of a pair of optical glasses. Also attached to cable 62 and screen 65 is elongated electrical cable 64 provided at one end with camera 63. In use, a user will assemble one of FONCPH devices and accessory 60 together by inserting portal connector 61 into the charge or accessory port 7, 17 or 27 of FONCPH devices 1, 11, or 21, respectively, and place the assembled FOHNCH device and accessory 60 into a user's ear by earpiece 2, 12, or 22, respectively. The user then places the assembled device and accessory on the User's nose bridge and may then aim the camera 63 to take a selfie, a picture of him/herself, by use voice command prompts to instruct the FONCPH device to activate the camera feature. The User can view the selfie on the display screens 65 by voice commanding the FONCPH device to activate the display screen feature.

When introducing elements of the present invention or the preferred embodiment(s) thereof, the articles “a”, “an”, “the”, and “said” are intended to mean there are one or more of the elements. The terms “comprising”, “including”, and “having” are intended to be inclusive and mean that there may be additional elements other than the listed elements. Also, the term “user” or “User” denotes a person using the FONCPH devices as described in the instant invention. Additionally, any description of the exemplary or preferred embodiments is intended to be read in connection with the accompanying drawings, which are to be considered part of the entire written description.

Additionally, the principles of the invention could be practiced by those of skilled in the art with equivalent alternative constructions. Although the present invention has been described in considerable detail with reference to a certain preferred embodiment thereof, other embodiments are possible. Therefore, the spirit and scope of the appended claims should not be limited to the description of the preferred embodiment(s) contained herein. The invention may be embodied and practiced in other specific forms without departing from the spirit and essential characteristics thereof. The present embodiments are therefore to be considered in all respects as illustrative and not restrictive, the scope of the invention being indicated by the appended claims rather than by the foregoing description; and all variations, substitutions and changes which come within the meaning and range of equivalency of the claims are therefore intended to be embraced therein.

What is claimed:

1: A hands free on call phone device comprising
a protruding tip capable of being inserted into a human ear and an oval shaped body and further wherein
the protruding tip is provided with aperture allowing for sound to be transmitted to an earphone located within the body and further wherein
the body is provided with a solar panel capable of powering the device and further wherein
the device is provided a camera and further wherein
the device is provided with a micro-phone and further wherein
the device is provided with a power button used to activate and deactivate the device and further wherein
the device is provided with electronic microchip hardware for operating the device and further wherein
the device is provided with a port allowing for the connection of an electrical charging appliance or other accessories to be connected to the device wherein
the device is capable of being used, after activation, by voice prompting of a user.

2: The device of claim 1 further wherein the solar panel is circular in shape.

3: The device of claim 1 further wherein the solar panel is semi-circular in shape.

4: The device of claim 1 further wherein the power button overlays the solar panel.

5: The device of claim 2 further wherein the device is provided with an electronic receiver and transmitter capable of connecting the device a terrestrial telecommunication system.

6: The device of claim 3 further wherein the device is provided with an electronic receiver and transmitter capable of connecting the device a terrestrial telecommunication system.

7: The device of claim 4 further wherein the device is provided with an electronic receiver and transmitter capable of connecting the device a terrestrial telecommunication system.

8: The device of claim 5 further wherein the device is provided with computer application software capable of processing signals received and transmitted by the device.

9: The device of claim 6 further wherein the device is provided with computer application software capable of processing signals received and transmitted by the device.

10: The device of claim 7 further wherein the device is provided with computer application software capable of processing signals received and transmitted by the device.

11: The device of claim 8 further wherein the device is provided with computer application software capable of producing and receiving audio command prompts for operating the device.

12: The device of claim 9 further wherein the device is provided with computer application software capable of producing and receiving audio command prompts for operating the device.

13: The device of claim 10 further wherein the device is provided with computer application software capable of producing and receiving audio command prompts for operating the device.

14: The device of claim 11 further wherein the device is provided with computer application software capable of providing an interactive voice menu for controlling the device via user voice prompting.

15: The device of claim 12 further wherein the device is provided with computer application software capable of providing an interactive voice menu for controlling the device via user voice prompting.

16: The device of claim 13 further wherein the device is provided with computer application software capable of providing an interactive voice menu for controlling the device via user voice prompting.

17: A hands free on call phone device comprising
a protruding tip capable of being inserted into a human ear and an oval shaped body and further wherein
the protruding tip is provided with aperture allowing for sound to be transmitted to an earphone located within the body and further wherein
the body is provided with a solar panel capable of powering the device and further wherein
the solar panel is circular in shape and further wherein
the device is provided a camera and further wherein
the device is provided with a micro-phone and further wherein
the device is provided with a power button used to activate and deactivate the device and further wherein
the device is provided with electronic microchip hardware for operating the device and further wherein
the device is provided with an electronic receiver and transmitter capable of connecting the device a terrestrial telecommunication system and further wherein
the device is provided with computer application software capable of processing signals received and transmitted by the device and further wherein
the device is provided with computer application software capable of producing and receiving audio command prompts for operating the device and further wherein
the device is provided with computer application software capable of providing an interactive voice menu for controlling the device via user voice prompting and further wherein
the device is provided with a port allowing for the connection of an electrical charging appliance or other accessories to be connected to the device wherein
the device is capable of being used, after activation, by voice prompting of a user.

18: An accessory for use with a hands free on call phone device comprising an elongated flexible electrical cable provided at one end with portal connector and at the opposite end with a camera and further wherein the accessory is provided with a second elongated flexible electrical cable affixed on one end with a visual display screen to assist and facilitate the taking of a user self-picture.

19: The accessory of claim 18 further wherein the second elongated flexible electrical cable is connected to the portal connector and further wherein the visual display screen incorporates touch-screen digitizer technology.

20: The accessory of claim 18 further wherein the visual display screen incorporates touch-screen digitizer technology and further wherein visual display screen comprises a pair of optical glasses.
